(19) United States
(12) Patent Application Publication
(10) Pub. No.: US 2007/0004171 A1
(43) Pub. Date: Jan. 4, 2007

(54) Method of supporting microelectronic wafer during backside processing using carrier having radiation absorbing film thereon

(76) Inventors: Leonel R. Arana, Phoenix, AZ (US); Edward R. Prack, Phoenix, AZ (US); Sudhakar N. Kulkarni, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/173,857

(22) Filed: Jun. 30, 2005

(51) Int. Cl. H01L 21/30; H01L 21/00

(52) U.S. Cl. 438/455; 438/458; 438/118

(57) ABSTRACT

A method of supporting a microelectronic wafer during backside processing. The method comprises: selecting a rigid carrier including a radiation absorbing film thereon, an adhesive, and a radiation source to emit radiation at a predetermined wavelength range; forming a wafer-carrier stack by providing the adhesive between the wafer and the carrier and curing the adhesive to bond the wafer to the carrier; subjecting the wafer in the wafer-carrier stack to backside processing; and removing the carrier and the adhesive from the wafer-carrier stack comprising detackifying the adhesive by irradiating the wafer-carrier stack from a carrier side thereof with radiation from the radiation source. The carrier is adapted to transmit therethrough at least some of the radiation from the radiation source. and the radiation absorbing film is adapted to absorb substantially all radiation transmitted through the carrier and is further adapted to be heated to detackify the adhesive as a result of absorbing said substantially all radiation.

### FIELD

Embodiments of the present invention relate to a method of supporting a wafer during backside processing.

### BACKGROUND

In the process of fabricating a microelectronic wafer (hereinafter “wafer”), backside processing is performed generally after a wiring pattern is provided on the front surface of the wafer. Backside processing may include mechanical or chemical methods for thinning the wafer, such as, for example, grinding, chemical-mechanical polishing, and etching. Backside processing may further include processes other than thinning, such as, for example, thin film deposition and/or electroplating. However, backside processing tends to negatively affect the strength and rigidity of the wafer, thus increasing the likelihood that the wafer may be damaged through breakage or warping, especially where the wafer has a thickness below about 300 microns.

In general, wafers that are to undergo backgrinding are typically mounted onto a flexible backgrinding tape. After grinding is complete, the tape is optionally detackified (with UV exposure using a lamp, for example) and then removed by peeling. If after backgrinding, the thinned wafer is to undergo processing (such as by way of metal or dielectric thin film deposition, polymer deposition/curing, etching, and electroplating), backgrinding tapes will typically not be sufficient to support the wafer. Most backgrinding tapes on the market are effective only to temperatures up to about 80 degrees Celsius, and even the best tapes under development are effective only to about 150 degrees Celsius. This means that if any of the additional processing involves a thermal exposure to temperatures above 150 degrees Celsius, backgrinding tapes are not a support option. In addition, many wafer handling and processing tools can only handle rigid wafers. Since backgrinding tapes and ultra-thin wafers (that is, wafer having a thickness below about 300 μm) are flexible, the tape/wafer stack in many cases does not exhibit the necessary rigidity.

As a result of the above, conventional methods have attempted to impart strength and rigidity to the wafer during backside processing as discussed below.

In particular, the Nitto Denko Corporation has developed a process in which a double-sided tape is laminated between a wafer and a rigid glass carrier. Thereafter, the wafer undergoes backside processing before being mounted onto a hot plate. The hot plate heats the wafer-carrier stack to a temperature sufficient to detackify the double-sided tape. The tape is then be peeled off to release the wafer. The above approach has as one of its disadvantages the fact that a maximum allowable temperature for backside processing is limited. Currently, the maximum allowable backside processing temperature of the Nitto process described above is limited to about 80 degrees Celsius.

Additionally, the 3M Company has developed a wafer support system based on a spin-on adhesive and a light to heat conversion layer (LTHC layer) on a glass wafer carrier. In the 3M process, a LTHC layer is provided on a glass carrier. Separately, an adhesive is applied to the front surface of a microelectronic wafer. The wafer-adhesive combination is then mounted to the glass carrier-LTHC combination by placing the LTHC layer and the adhesive in contact. The combination thus formed is then cured, such as by using UV radiation, so that the adhesive hardens to fix the wafer-adhesive combination to the glass carrier-LTHC combination, thus forming the stack. Once the stack is formed, the backside of the wafer is subjected to backside processing. Subsequent, the thus processed wafer-carrier stack is mounted to a dicing tape at the backside of the wafer, and subjected to laser radiation in order to detackify the adhesive. The remaining film is subsequently removed by peeling. The above approach has as one of its disadvantages that the maximum backside processing temperature it allows is limited to less than 250 degrees Celsius. Above this temperature, the films delaminate, generate voids, and/or outgas such that they compromise the integrity of the wafer stack and possibly damage the supported wafer. Additionally, because the LTHC layer is highly opaque to the visible spectrum, it obstructs from view front-side wafer fiducials needed for aligned backside processing of the wafer.

Additional wafer support systems have been proposed that involve the use of a solvent or chemical stripper to detach the wafer from the rigid carrier, as mentioned above. In such systems, a strippable adhesive is sandwiched between the wafer and a perforated rigid carrier, such as a silicon carrier. After backside processing, the wafer-carrier stack may be mounted to a secondary carrier, such as dicing tape, at the backside of the wafer, and the wafer and adhesive are then removed by applying a chemical stripper appropriate for the adhesive selected. The stripper is applied such that it reaches the adhesive through the perforations provided in the rigid carrier, and dissolves the adhesive to allow a disassembly of the wafer-carrier stack. Certain silicone adhesives, such as Gentak 330 from General Chemical, are known to work moderately well for the above application. One disadvantage of the above regime is that it requires ensuring compatibility of the chemical stripper with the secondary carrier, thus limiting the choice of appropriate adhesives for the wafer-carrier stack. In addition, few secondary carriers (including dicing tape) are compatible with the chemical strippers used for silicone stripping. Therefore, a secondary carrier often cannot be applied prior to stripping of the silicone adhesive, and some degree of thin wafer handling may be required. Another drawback of this approach is that long soak times (in excess of several hours) are required to fully dissolve the adhesive and remove the perforated carrier. The use of a perforated carrier (in contrast to a flat carrier such as a bare glass wafer) has additional drawbacks including high cost (perforated carriers are costly to produce) and inferior backgrinding performance for ultra thin wafers (the nonuniformity introduced by the perforations can translate into thickness nonuniformity in the background wafer).

A method of supporting a microelectronic wafer during backside processing is therefore needed that circumvents the disadvantages of the prior art as noted above.

### BRIEF DESCRIPTION OF THE DRAWINGS

Embodiments of the present invention are illustrated by way of example and not by way of limitation in the figures of the accompanying drawings, in which like references indicate similar elements and in which:

FIG. 1 is a schematic, cross-sectional view of a conventional microelectronic wafer;

FIG. 2 is a schematic, cross-sectional view of a wafer-adhesive combination according to one embodiment including the wafer of FIG. 1;

FIG. 3 is a schematic, cross-sectional view of an intermediate wafer-carrier stack formed from the wafer-adhesive combination of FIG. 2 according to one embodiment;

FIG. 4 is a schematic, cross-sectional view of a wafer-carrier stack, formed from the intermediate wafer-carrier stack of FIG. 3, according to one embodiment;

FIG. 5 is a schematic, cross-sectional view of the wafer-carrier stack of FIG. 4 being subjected to backside processing according to one embodiment;

FIG. 6 is a schematic, cross-sectional view of a processed wafer-carrier stack formed from the wafer-carrier stack of FIG. 4 by way of backside processing and placed on a dicing tape according to one embodiment;

FIG. 7 is a schematic, cross-sectional view of a modified wafer-carrier stack formed from the processed wafer-carrier stack of FIG. 6 by way of irradiation according to one embodiment;

FIG. 8 is a schematic, cross-sectional view of the carrier being removed from the modified wafer carrier stack of FIG. 7 to leave behind a modified wafer-adhesive combination according to one embodiment;

FIGS. 9a and 9b are schematic, cross-sectional views of the modified wafer-adhesive combination of FIG. 8 being subjected to adhesive removal according to two respective embodiments; and

FIG. 10 is a schematic, cross-sectional view of the processed wafer resulting from the adhesive removal depicted in any of FIG. 9a or 9b according to one embodiment.

### DETAILED DESCRIPTION

A method for supporting a microelectronic wafer during backside processing is disclosed herein.

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention; however, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising ”, “having” and “including” are synonymous, unless the context dictates otherwise.

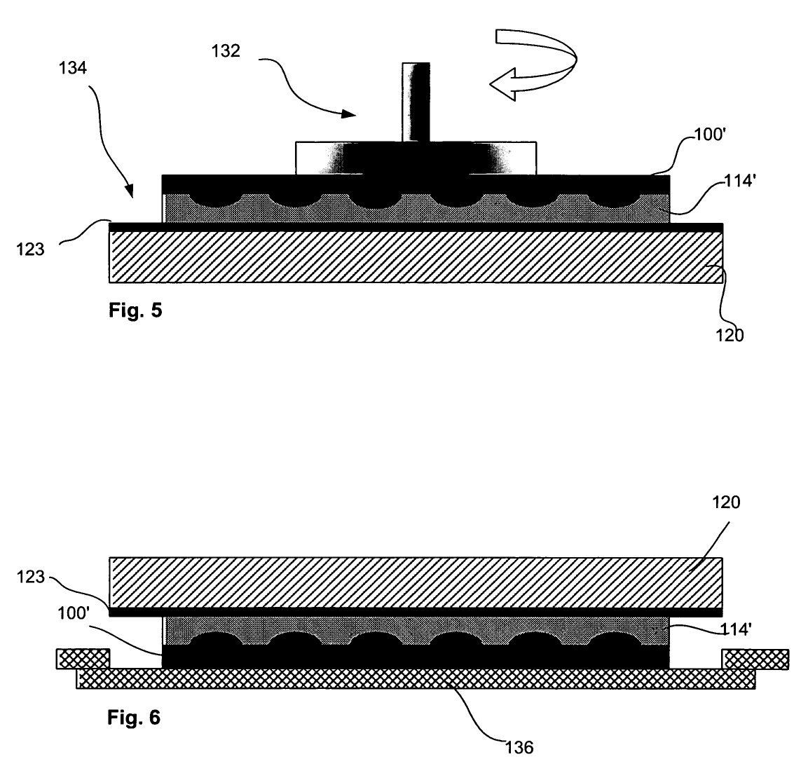

According to embodiments of the present invention, a system is provided to support a wafer during backside processing. Referring first to FIGS. 4, 5 and 7, the system includes a rigid carrier including a radiation absorbing film thereon, and an adhesive adapted to be placed on the radiation absorbing film of the rigid carrier to bond a microelectronic wafer to the rigid carrier. An embodiment of such a system is shown by way of example in FIG. 4, and includes a rigid carrier 120 including a radiation absorbing film (RAF) 123 thereon, a cured adhesive 114′, the system bonding a wafer 100 to the rigid carrier 120 by way of the adhesive 114′. According to embodiments of a method according to the present invention, the RAF may be provided on a surface of the rigid carrier, and the adhesive may be placed between the wafer and the RAF to bond the wafer to the rigid carrier to form a wafer-carrier stack, such as stack 126 as seen in FIG. 4. The wafer may then be subjected to backside processing, as seen for example in FIG. 5, while supported by the rigid carrier via the adhesive. Thereafter, the wafer-carrier stack may be subjected to radiation from a radiation source (hereinafter “incident radiation”) to detackify the adhesive, such that at least some of the incident radiation is transmitted through the rigid carrier and reaches the adhesive. For example, as seen in FIG. 7, the wafer-carrier stack 126 is subjected to incident radiation 138 from a radiation source 140, at least some of the incident radiation being transmitted through the rigid carrier 120 in order to reach the RAF, to heat the RAF and to thus detackify the adhesive for carrier removal after backside processing. A RAF may thus be chosen that is adapted to absorb substantially all of the radiation transmitted through the rigid carrier (hereinafter “transmitted radiation”) and is adapted to generate heat as a result of such radiation absorption to thus detackify the adhesive. In addition, a carrier is chosen that is transparent to the radiation in the wavelength range adapted to be absorbed by the RAF. Each stage for using a wafer support system according to method embodiments will be described in further detail below.

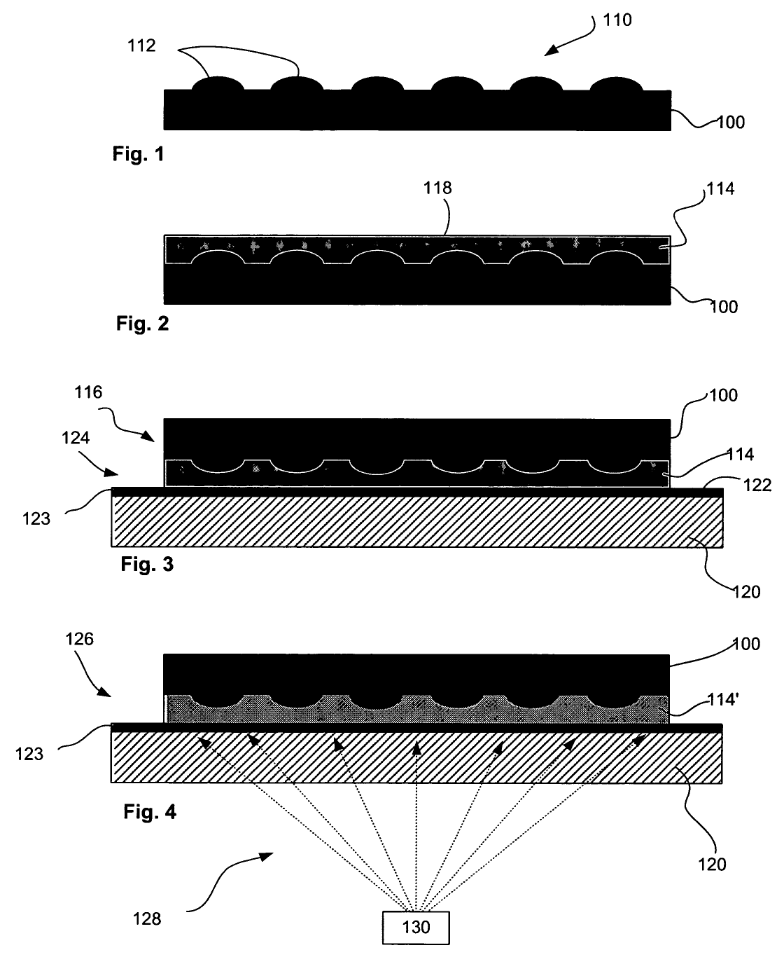

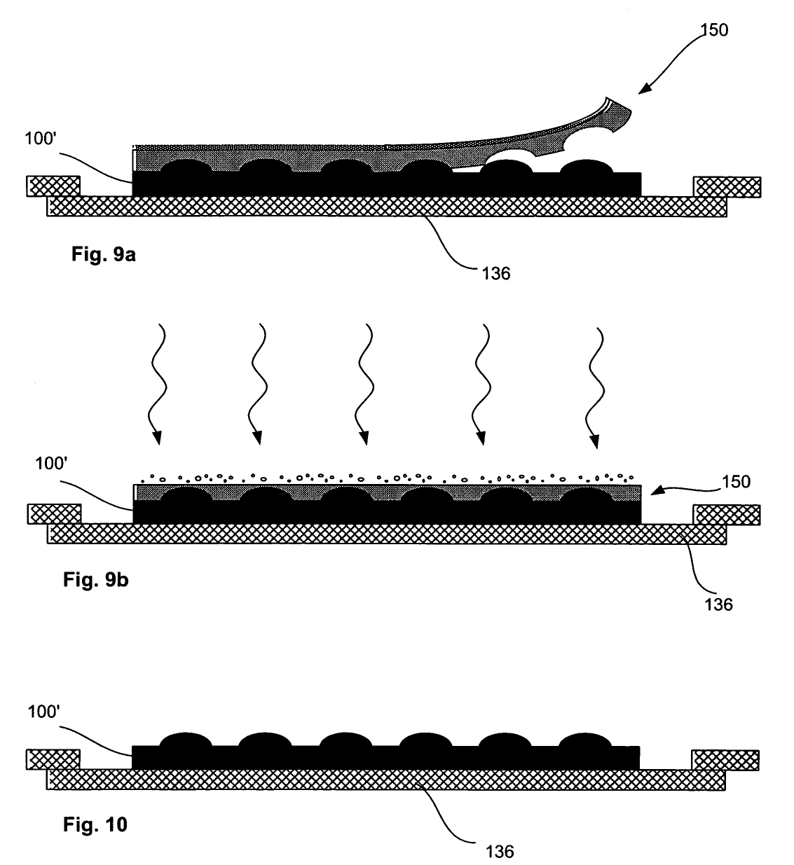

FIGS. 1-8 and 9a-9b depict various stages of a method for supporting a wafer during backside processing according to two embodiments of the present invention. In particular, while stages depicted in FIGS. 1-8 are common to both of the mentioned two embodiments, FIG. 9a depicts one of the two embodiments, and FIG. 9b depicts an alternate one of the two embodiments. It is noted that the stages depicted in FIGS. 1-9b are exemplary only, and that variations to the same would be possible within the scope of embodiments of the present invention.

Referring first to FIG. 1, a first stage of a method of supporting a wafer according to embodiments of the present invention includes providing a microelectronic wafer, such as wafer 100, having a patterned front surface, such as patterned front surface 110. By patterned front surface, what is meant in the context of embodiments of the present invention is a surface of the wafer including an interconnection pattern thereon formed according to any one of well known methods. The wafer may further include any one of well known materials for making microelectronic wafers, such as silicon, and may further include bumps 112 thereon as part of the aforementioned pattern.

Referring next to FIG. 2, a next stage of a method of supporting a wafer according to one embodiment of the present invention includes providing an adhesive on the patterned front surface of the wafer. For example, as shown in FIG. 2, an adhesive film 114 may be provided onto patterned front surface 110. Preferably, according to an embodiment, the adhesive provided comprises a single film of adhesive, as shown by way of example by film 114 in FIG. 2. Preferably, according to an embodiment, the adhesive is provided in such as way as to substantially cover the patterned front surface of the wafer in order to protect the interconnection pattern of the wafer during backside processing, and further in order to provide maximum adhesive surface area contact with the wafer on the one hand and with the rigid carrier (see paragraph below) on the other hand. According to one embodiment, the adhesive may be provided by spin-coating, spray-coating or lamination. Embodiments of the present invention encompass within their scope additional processing on the wafer after application of the adhesive, such as, for example, soft baking or lithographic exposure. Providing the adhesive on the wafer results in the formation of a wafer-adhesive combination 116 where the adhesive 114 exhibits a free surface 118 as shown in FIG. 2.

According to embodiments, an adhesive may be chosen that offers necessary wafer support and exhibits necessary properties to survive the chemical and thermal exposures associated with backside processing. Thus, any adhesive that achieves the desired performance for backside processing may be used according to embodiments. Preferably, the adhesive used is further highly transparent in the visible spectrum (that is, at a wavelength range between about 400 and about 700 nm) in order to allow fiducials on the wafer to be viewed through the adhesive. Additionally, adhesives that decompose cleanly upon heating, such as, for example, certain polynorbornenes (e.g. Unity series from Promerus, LLC) and poly (alkyl carbonates) (e.g. QPAC series from Empower Materials) are preferred according to embodiments in order to minimize residue formation. Embodiments further encompass the use of adhesives such as polysiloxanes (silicones), polyacrylates (acrylic), epoxies, polyimides or copolymers.

Referring next to FIG. 3, a next stage of a method of supporting a wafer according to an embodiment of the present invention includes providing a rigid carrier for the wafer-adhesive combination, the rigid carrier including a RAF thereon, and placing the rigid carrier in contact with the wafer-adhesive combination such that a free surface of the adhesive and a surface of the RAF are in contact. By “rigid carrier,” what is meant in the context of embodiments of the present invention is a carrier made of a material that does not substantially bend or warp or otherwise change shape during backside processing of the wafer and during removal of the carrier from the wafer according to embodiments. For example, as seen in FIG. 3, according to an embodiment, a rigid carrier 120 may be provided and be placed in contact with the wafer-adhesive combination 116 such that the free surface 118 (FIG. 2) of the adhesive 114 and a surface 123′ of the RAF 123 on the rigid carrier 120 are in contact. According to embodiments, the rigid carrier comprises a rigid substrate, preferably comparable in size to a size of the wafer, although potentially thicker. For example, the carrier may be several times, such as, for example, 20 times or more, thicker than the wafer if the wafer has been thinned. The carrier may be comparable (probably within about 50%) of the thickness of a standard Si wafer (e.g. ˜0.8 mm for a 300-mm-diameter wafer), so that the carrier/wafer stack is rigid. Examples of the rigid carrier according to embodiments include borosilicate glass, such as, for example, Pyrex 7740, manufactured by Corning Incorporated, or Borofloat Borosilicate Float Glass, manufactured by Schott Glass. Thin wafers of such materials, for example, wafers having a thickness under about 1 mm exhibit a transmittance at least about 90% in a wavelength range between about 300 nm and about 2700 nm. Optionally, a carrier material with a broader transmittance range may be used, such as, for example, quartz. For example, wafers of synthetic fused silica, a form of quartz, have at least about 90% transmittance in a wavelength range between about 170 nm and about 2500 nm. Additionally, according to embodiments, the rigid carrier is adapted to transmit therethrough at least a wavelength range of the incident radiation that the RAF is adapted to substantially fully absorb. By “substantially fully,” what is meant in the context of the instant description is at least about 90%. Preferably, the rigid carrier is adapted to transmit substantially all of the incident radiation. More preferably, the carrier, the RAF and the adhesive may be substantially fully transparent in the visible spectrum, that is, in a wavelength range between about 400 nm and about 700 nm, such that any fiducials on the front surface of the microelectronic wafer may be referenced during backside processing.

According to embodiments, the RAF may comprise a thin inorganic film including a radiation absorbing material adapted to absorb at least about 80% of the incident radiation. Preferably, the RAF is made of any material that is deposited onto the carrier to a sufficient thickness to absorb at least 90% of radiation transmitted to the RAF through the carrier. Wavelengths near 355 nm and/or 266 nm may be used, which are, respectively, two common laser wavelengths. Such materials may include zinc oxide, tin oxide, indium oxide or combinations of the same. For example, it has been shown that a 150-nanometer-thick undoped zinc oxide film absorbs virtually 100% of radiation at 355 nm (corresponding to the wavelength of radiation emitted by a tripled-YAG laser), yet is highly transparent throughout the entire visible spectrum, that is, between about 400 to about 700 nm. See K. H. Kim, K. C. Park and D. Y. Ma, J. Appl. Phys, 81 (12), 15, Jun. 1997. In addition, indium tin oxide film on polyethylene terepthalate (PET) deposited under different oxygen admixtures have been shown to absorb about 90% of radiation at 355 nm, and to yet be highly transparent in the visible region. See Y. S. Kim, Y. C. Park, S. G. Ansari, J. Y. Lee, B. S. Lee, H. S. Shin, “Surface and Coatings Technology” 173 (2003), 299-308. The RAF may be deposited onto the rigid carrier according to any one of well known methods, such as, for example, physical vapor deposition, or chemical vapor deposition, or wet chemical deposition. According to one embodiment, the RAF includes on a surface thereof surface topography (not shown), such as inverted cylinders and/or waveguides to improve radiation absorption at wavelengths of the incident radiation. According to embodiments, the surface topography on the RAF may include any topography shape that would modify a surface area of the RAF to enhance an absorptivity thereof to the radiation being transmitted thereto through the carrier. When the wafer and rigid carrier including the RAF thereon are joined with the adhesive sandwiched in between, and when the adhesive is still in its uncured or partially-cured phase, such as, for example, adhesive 114, the combination is hereinafter referred to as an intermediate wafer-carrier stack, denoted by reference numeral 124 in FIG. 3.

According to a preferred embodiment, the rigid carrier is more than about 90% transparent to the incident radiation. In such a case, a RAF may be selected that is adapted to absorb most radiation (that is at least about 80% of the radiation) at a wavelength range of the radiation source being used. For example, as seen in FIG. 7, the carrier 120 is subjected to incident radiation 138 from a radiation source 140, at least about 90% of the incident radiation being transmitted through the rigid carrier 120 in the form of transmitted radiation 142 in order to reach the RAF 123 to heat the RAF and to thus detackify the adhesive in contact with the RAF. Thus, according to one embodiment, the rigid carrier may be selected to transmit at least about 90% of the incident radiation. In such a case, the RAF will absorb at least about 90% of the transmitted radiation, and at least about 80% of the incident radiation.

It is to be noted that embodiments of the present invention are not limited to provision of the adhesive on the wafer prior joining the wafer and the rigid carrier. Thus, embodiments of the present invention include within their scope the provision of an adhesive, such as any one of the adhesives discussed above, in between a microelectronic wafer and a RAF on a rigid carrier, in order to form a wafer-carrier stack such as stack 126 shown in FIG. 4. As a result, according to one embodiment, the adhesive may first be provided on the RAF on the rigid carrier and the wafer then placed onto the adhesive layer to form a stack such as stack 126 of FIG. 4. In the alternative, according to another embodiment, the adhesive may be provided both on the wafer and on the RAF on the rigid carrier before assembling the wafer and the rigid carrier into intermediate stack 124. According to another embodiment, multiple layers of adhesive may be used. According to one embodiment, a double sided tape (not shown) may be sandwiched between the wafer and the RAF on the carrier. Thus, rather than applying the adhesive onto the wafer and/or the RAF on the carrier, it is also possible to pre-apply the adhesive onto a base film to make a double sided tape. The base film could be of a high-temperature stable material, such as polyimide. The pre-applied adhesive on both sides of the base film could be any of the adhesives listed above. Use of a double-sided tape advantageously facilitates the peeling of the adhesive or adhesive residue. If a double sided tape is used, curing of the adhesive after bonding the carrier to the wafer (as described in the next paragraph) may not be necessary. The adhesive may be provided between the wafer and the RAF on the rigid carrier in any other way as would be within the knowledge of one skilled in the art.

Referring next to FIG. 4, a next stage of a method of supporting a wafer according to an embodiment of the present invention includes curing the adhesive in order to harden the same to bond the wafer to the carrier. For example, as seen in FIG. 4, a wafer-carrier stack 126 may be formed by curing the adhesive 114 through radiation 128, such as UV radiation, from radiation source 130, to harden the same into cured adhesive 114′ as shown thus bonding the wafer 100 to carrier 120. In addition to radiation as shown in FIG. 4, curing may be performed in any manner within the knowledge of one skilled in the art, such as through heating of the wafer stack, degassing or air-curing. The curing sets the adhesive in place and prevents it from flowing, thus resulting in the formation of wafer-carrier stack 126 as shown in FIG. 4.

Referring next to FIG. 5, a next stage of a method of supporting a wafer according to embodiments of the present invention includes subjecting the wafer to backside processing, such as, for example, grinding, chemical-mechanical polishing, thin film deposition, etching and/or electroplating. For example, as shown in FIG. 5, a grinding tool 132 may be used to thin the wafer in a backgrinding process while the wafer is supported by the wafer support system including the adhesive 114′ and the rigid carrier 120. As seen in FIG. 5, one result of backside processing may involve a thinning of the wafer, thus justifying a need for a wafer support system in the first instance. The Wafer may further be subjected, among others, to processes such as metal or dielectric film deposition, polymer deposition/curing, etching, or electroplating (not shown) as part of backside processing. Subjecting the wafer to backside processing results in the formation of a processed wafer-carrier stack 134 as shown in FIG. 5, including a processed wafer 100′.

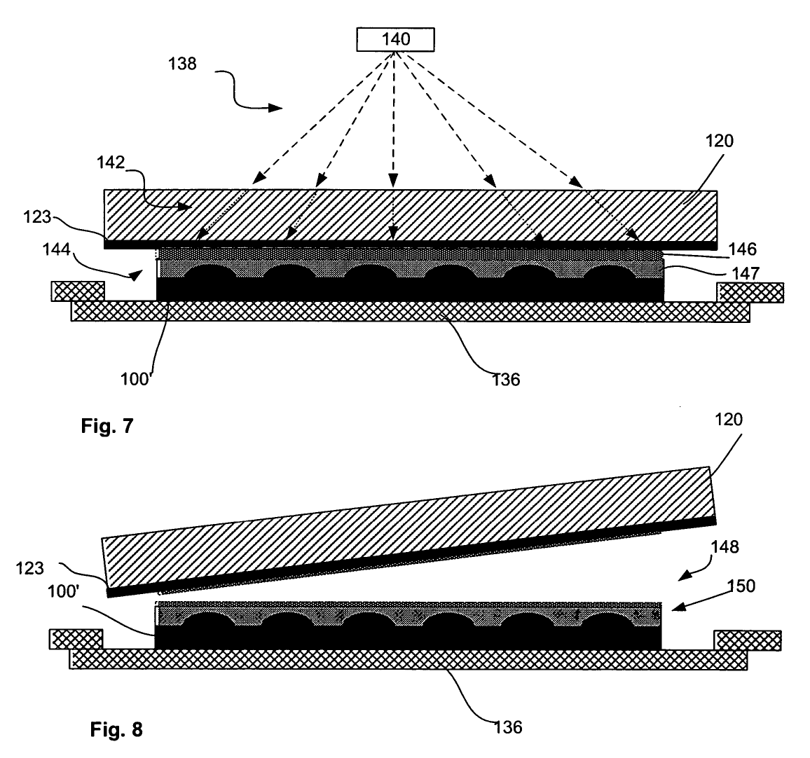

Referring next to FIG. 6, a next stage of a method of supporting a wafer according to embodiments of the present invention includes placing the processed wafer-carrier stack on a wafer carrying system at a backside of the wafer. A function of the wafer carrying system is to support the wafer after the wafer support system is removed. For example, processed wafer-carrier stack 134 may be transferred to a dicing tape 136 as shown in FIG. 6.

Referring next to FIG. 7, a next stage of a method of supporting a wafer according to embodiments of the present invention includes detackifying the cured adhesive by subjecting the processed wafer-carrier stack to incident radiation from a carrier side of the processed wafer-carrier stack, the incident radiation having a wavelength range that is adapted to be at least in part transmitted by the carrier to result in transmitted radiation, the transmitted radiation further being in a wavelength range that is adapted to be substantially fully absorbed by the RAF to heat the RAF to detackify the adhesive. According to embodiments, detackifying the adhesive means reducing the tack (i.e. adhesion strength) of the adhesive sufficiently to allow removal of the carrier. Thus, detackifying includes within its scope a reduction in the tack of the adhesive that is localized, for example, limited to the RAF-adhesive interface. Additionally, detackifying includes within its scope a reduction in the tack of the adhesive to zero or near-zero, either locally or entirely. What is meant by a “near-zero” reduction in the tack of the adhesive in the context of the instant description is that the tack is reduced enough that the carrier can be easily removed without any peeling action (since peeling is not an option for a rigid carrier) and without damaging the Si wafer. As shown in FIG. 7, the processed wafer-carrier stack 134 may be subjected to incident radiation 138 from a radiation source 140. According to embodiments, a combination of an radiation source/rigid carrier/RAF/adhesive may be selected such that: (1) a wavelength of the radiation source is adapted to be at least in part transmitted through the carrier to the RAF in the form of transmitted radiation, such as transmitted radiation 142; and (2) the transmitted radiation is adapted to be substantially fully absorbed by the RAF to heat the RAF to detackify the adhesive. It is noted that although the incident radiation may be refracted by the rigid carrier, such refraction is not shown in FIG. 7. Additionally, although the incident radiation is depicted in FIG. 7 in the form of a number of arrows suggesting simultaneous radiation across the carrier, embodiments of the present invention are not so limited. In fact, preferably, the incident radiation may be scanned across a surface of the rigid carrier. More preferably, the radiation source may be a laser source. A large number of wavelengths in the near-UV range may be obtained, for example, using standard laser technologies. According to one embodiment, an excimer laser may be used as the radiation source, with UV wavelengths including, by way of example, 157 nm, 193 nm, 248 nm, 308 nm or 351 nm. In the alternative, a YAG laser may be used as the radiation source, with UV wavelengths including, by way of example, 262 nm, 263 nm, 266 nm, 349 nm, 351 nm, 355 nm. Preferably, according to embodiments, a high powered laser, such as, for example, a laser delivering between about 0.01 and about 1 Watt, is used. According to embodiments, during irradiation of the processed wafer-carrier stack, the carrier-adhesive interface may be ablated such that at least the adhesive at the interface loses its tack to zero or to near-zero.

Irradiation results in a modified wafer-carrier combination, such as modified wafer-carrier stack 143 shown in FIG. 7. The modified wafer-carrier stack includes the carrier, the RAF and the wafer, and may further include a remaining adhesive layer therebetween. For example, as shown in FIG. 7, the modified wafer-carrier stack 143 includes carrier 120, RAF 123, processed wafer 100′, and a modified adhesive layer 144 therebetween. In the shown embodiment of FIG. 7, modified adhesive layer 144 includes a layer of adhesive residue 146 (that is, a layer of adhesive that has lost its tack), and a layer of remaining cured adhesive 147. In the alternative, if the entire cured adhesive has had its tackiness reduced to zero or near zero through irradiation (not shown), the modified adhesive layer 144 would include only a layer of adhesive residue. Alternatively still, if irradiation vaporizes the adhesive, the modified adhesive layer 144 could include only a layer of remaining cured adhesive (not shown), a space existing between the remaining cured adhesive and the rigid carrier where the adhesive has been vaporized. Embodiments of the present invention further include within their scope a substantially complete vaporization of the adhesive 114′, such that no modified adhesive layer would exist between the wafer and the carrier (not shown). In the latter case, the modified wafer-carrier stack would consist of the carrier and the wafer.

Referring next to FIG. 8, a next stage of a method of supporting a wafer according to embodiments of the present invention includes removing the rigid carrier from the modified wafer-carrier stack to leave a modified wafer-adhesive combination. In the shown embodiment of FIG. 8, some of the adhesive residue remains on a bottom surface of the rigid carrier 120, and some of the adhesive residue remains on the remaining cured adhesive 146. The modified wafer-adhesive combination 148 shown in the embodiment of FIG. 8 thus includes the processed wafer 100′ and part of the modified adhesive layer 144 in the form of modified adhesive 150. “Modified adhesive” as used herein denotes any adhesive remaining on the processed wafer after carrier removal. According to one embodiment, any adhesive residue on the carrier may advantageously be removed therefrom according to any one of conventional methods, thus advantageously allowing the carrier to be re-used as part of a wafer support system according to embodiments. According to one embodiment, if no residue should remain on the carrier, the modified wafer-adhesive combination would include the processed wafer 100′ and substantially the entire modified adhesive layer 144.

Referring next to FIGS. 9a and 9b, a next stage of a method of supporting a wafer according to embodiments of the present invention includes substantially removing any modified adhesive from the modified wafer-adhesive combination. For example, as seen in FIGS. 9a and 9b, modified adhesive 150 may be removed from processed wafer 100′ such as by peeling, as shown in FIG. 9a, or by heating as shown in FIG. 9b by the meandering arrows, if the decomposition temperature of the adhesive is compatible with the dicing tape being used. Removal of any modified adhesive through heating would be appropriate where the adhesive selected decomposes relatively cleanly. Optionally, removal of any modified adhesive through heating may occur after dicing of the wafer by heating the individual chips (not shown). Other ways of removing any modified adhesive according to embodiments include chemical stripping, peeling, snow or pellet cleaning (such as with solid carbon dioxide particles), plasma cleaning or any other chemical or mechanical technique as would be within the knowledge of one skilled in the art. Removal of any modified adhesive results in a processed wafer 100′ with no substantially no adhesive thereon, as shown for example in FIG. 10.

A release process of the rigid carrier from the wafer-carrier stack according to embodiments of the present invention may accordingly involve a matching of a rigid carrier, a RAF, an adhesive and a radiation source to enable ablation of the adhesive at the adhesive-RAF interface by radiation from the source being transmitted through the carrier. Thus, a matching according to embodiments would include selecting a rigid carrier, a RAF, an adhesive and an radiation source adapted to emit radiation at a predetermined wavelength range such that: (1) the rigid carrier is adapted to transmit therethrough at least some of radiation from the radiation source; (2) the RAF is adapted to absorb substantially all of the radiation transmitted through the carrier and is further adapted to be heated as a result of such absorption; (3) the adhesive is adapted be detackified as a result of a heating of the RAF; and (4) the radiation source is adapted to emit radiation at the predetermined wavelength range such that at least some of the radiation is adapted to be transmitted through the carrier, and such that the thus transmitted radiation is adapted to be substantially fully absorbed by the RAF to heat the RAF to detackify the adhesive.

Advantageously, embodiments of the present invention provide surface modifications for the rigid carrier, such as inorganic radiation absorbing films and/or surface topography modifications of the films, that inherently exhibit high temperature stability, thus allowing the carrier to be reused. In addition, advantageously, embodiments of the present invention allow flexibility in the choice of adhesive being used, since it is only necessary that the adhesive used according to embodiments give good backgrinding performance and be thermally stable in the temperature range to which it will be exposed during the backgrinding process, and since the adhesive is not required to absorb at any specific wavelength. Additionally, embodiments of the present invention further obviate a need for additional layers in the wafer-carrier stack, such as, for example, LTHC's, thus leading to a more simple and efficient method of supporting the wafer during backside processing. Moreover, to the extent that embodiments of the present invention do not require an LTHC layer, they allow the fiducials on the front surface of the wafer to be seen during backside processing, if a carrier, RAF and adhesive transparent in the visible spectrum are used. Additionally, advantageously, since a radiation absorbing film according to embodiments is adapted to absorb substantially all of radiation transmitted to it through the carrier, embodiments of the present invention advantageously substantially guard against damage to the wafer components from radiation reaching the same.

A technical basis for embodiments of the present invention thus involves: (1) a radiation absorbing film on a surface of a rigid carrier that will absorb radiation at a predetermined wavelength range, and that will heat up when bombarded with radiation within that wavelength range; and (2) an adhesive, such as a polymeric adhesive, that will detackify when heated above a predetermined temperature. The above two factors may be used to design a wafer support system for supporting a wafer during backside processing. For example, a glass carrier that is highly transparent to the visible spectrum, that is, in a wavelength range between about 400 nm and about 700 nm, and to the wavelength of radiation used for releasing the carrier from the wafer may be used according to embodiments. An example of a material for the rigid carrier includes borosilicate glass, as it can be CTE matched to a wafer made of silicon, and is highly transparent (substantially fully transmits) radiation at wavelengths between 250 nm and 700 nm. According to an embodiment, one surface of the rigid carrier may be coated with a UV absorbing inorganic film (an example of the RAF), such that the surface of the inorganic film substantially fully absorbs radiation at the wavelength range used for releasing the carrier from the wafer, yet is transparent to radiation in the visible spectrum. Such a surface modification of the rigid carrier could, for example, include a coating of zinc oxide, which absorbs nearly 100% of radiation up to about 365 nm, yet is highly transparent from about 400 to about 700 nm. Zinc oxide is further known to be highly thermally stable up to about 700 degrees Celsius. The rigid carrier may then be bonded to the silicon wafer using an adhesive such that the modified surface of the rigid carrier faces the adhesive. With the glass carrier attached thereto, the silicon wafer could, according to embodiments, under backside processing, which, when complete, would be followed by release of the carrier from the silicon wafer. Release of the carrier from the silicon wafer according to an embodiment may include irradiation the carrier side with radiation that is transmitted substantially fully through the bulk of the carrier, yet is absorbed substantially fully at the UV absorbing film. For example, a tripled-YAG laser with a wavelength of 355 nm may be used with a glass carrier (highly transparent to radiation at 355 nm) with a coating of ZnO, which is nearly 100% opaque to radiation at 355 nm. According to an embodiment, radiation transmitted through the rigid carrier is then substantially fully absorbed by the UV absorbing film at the carrier/adhesive interface, thus locally heating such interface. A localized heating of the carrier may then result in localized heating of the adjacent adhesive, thus detackifying the same. The rigid carrier may then be easily removed, and the adhesive subsequently removed according to well known methods.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A method of supporting a microelectronic wafer during backside processing comprising:
providing a wafer-carrier stack comprising a microelectronic wafer, a rigid carrier having a radiation absorbing film on a surface thereof; and a cured adhesive between the wafer and the radiation absorbing film, the cured adhesive bonding the wafer and the carrier to one another to form the wafer-carrier stack;
subjecting the wafer to backside processing while the wafer is part of the wafer-carrier stack to yield a processed wafer-carrier stack including a processed form of the wafer;
detackifying the cured adhesive in the processed wafer-carrier stack to yield a modified wafer-carrier combination, detackifying comprising subjecting the processed wafer-carrier stack to radiation such that at least some of the radiation is transmitted through the carrier to the radiation absorbing film, the radiation absorbing film being configured to absorb said at least some of the radiation and being heated as a result thereof to detackify the cured adhesive;
removing the carrier from the modified wafer-carrier combination to yield a modified wafer-adhesive combination;
removing any adhesive remaining on the modified wafer-adhesive combination.

2. The method of claim 1, wherein the radiation absorbing film comprises an inorganic material.

3. The method of claim 1, wherein the radiation absorbing film comprises zinc oxide, tin oxide, indium oxide or combinations thereof.

4. The method of claim 1, wherein providing a wafer-carrier stack comprises:
providing the wafer;
providing the carrier;
providing the radiation absorbing film on a surface of the carrier;
providing adhesive between the wafer and the radiation absorbing film on the carrier;
curing the adhesive to yield the cured adhesive to bond the wafer and the carrier to one another.

5. The method of claim 4, wherein providing the radiation absorbing film comprises using physical vapor deposition to deposit the radiation absorbing film on the surface of the rigid carrier.

6. The method of claim 4, wherein providing an adhesive comprises:
disposing adhesive on the wafer to yield a wafer-adhesive combination; and
placing the rigid carrier including the radiation absorbing film thereon in contact with the wafer-adhesive combination such that a free surface of the adhesive and a free surface of the radiation absorbing film on the rigid carrier are in contact.

7. The method of claim 4, wherein curing comprises subjecting the adhesive to one of radiation and heat.

8. The method of claim 1, wherein subjecting the wafer to backside processing includes at least one of exposing a backside of the wafer to backgrinding, chemical-mechanical polishing, etching, thin film deposition and electroplating.

9. The method of claim 1, wherein detackifying comprises using a laser source to generate the radiation.

10. The method of claim 9, wherein using the laser source comprises scanning the radiation across a free surface of the carrier.

11. The method of claim 9, wherein radiation comprises laser radiation at a wavelength between about 150 nm and about 360 nm.

12. The method of claim 1, wherein removing any adhesive comprises subjecting the modified wafer-adhesive combination to heating.

13. The method of claim 1, wherein removing any adhesive comprises subjecting the modified wafer-adhesive combination to one of snow-cleaning, chemical stripping, peeling, pellet cleaning, and plasma cleaning.

14. The method of claim 1, wherein the carrier is adapted to transmit at least about 90% of the radiation.

15. The method of claim 1, wherein the radiation absorbing film is adapted to absorb at least about 90% of radiation at a wavelength between about 250 nm and 400 nm.

16. The method of claim 15, wherein the radiation absorbing film is adapted to transmit at least about 50% of radiation at a wavelength between about 400 nm and about 700 nm.

17. The method of claim 1, wherein the radiation absorbing film is adapted to absorb at least about 90% of radiation at a wavelength between about 250 nm and about 400 nm after being used five times.

18. A method of supporting a microelectronic wafer during backside processing comprising:
selecting a rigid carrier including a radiation absorbing film on a surface thereof, an adhesive, and a radiation source to emit radiation at a predetermined wavelength range, wherein the carrier is adapted to transmit therethrough at least some of the radiation from the radiation source; and the radiation absorbing film is adapted to absorb substantially all radiation transmitted through the carrier and is further adapted to be heated to detackify the adhesive as a result of absorbing said substantially all radiation;
forming a wafer-carrier stack by providing the adhesive between the wafer and the carrier and curing the adhesive to bond the wafer to the carrier;
subjecting the wafer in the wafer-carrier stack to backside processing;
removing the carrier, including the radiation absorbing film thereon, and the adhesive, from the wafer-carrier stack, removing comprising detackifying the adhesive by irradiating the wafer-carrier stack from a carrier side thereof with radiation from the radiation source.

19. The method of claim 18, wherein the radiation absorbing film comprises an inorganic material.

20. The method of claim 18, wherein the radiation absorbing film comprises zinc oxide, tin oxide, indium oxide or combinations thereof.

21. The method of claim 18, wherein the carrier is adapted to transmit therethrough at least about 90% of the radiation from the radiation source.

22. The method of claim 18, wherein the radiation absorbing film is adapted to absorb at least about 90% of radiation at a wavelength between about 250 nm and 400 nm.

23. The method of claim 22, wherein the radiation absorbing film is adapted to transmit at least about 50% of radiation at a wavelength between about 400 nm and about 700 nm.

24. The method of claim 18, wherein the radiation absorbing film is adapted to absorb at least about 90% of radiation at a wavelength between about 250 nm and about 400 nm after being used five times.

25. The method of claim 18, wherein detackifying comprises using a laser source to scan the radiation across a free surface of the carrier.

26. The method of claim 18, wherein the laser source is adapted to emit radiation at a wavelength between about 150 nm and about 360 nm.

27. The method of claim 18, wherein removing the adhesive comprises heating any adhesive on the wafer after removing the carrier.

28. The method of claim 18, wherein removing any adhesive comprises subjecting said any adhesive to one of snow-cleaning, chemical stripping, peeling, pellet cleaning, and plasma cleaning.

29. The method of claim 18, wherein providing a wafer-carrier stack comprises:
providing the wafer;
providing the carrier;
providing the radiation absorbing film on a surface of the carrier;
providing adhesive between the wafer and the radiation absorbing film on the carrier;
curing the adhesive to yield the cured adhesive to bond the wafer and the carrier to one another.

30. The method of claim 29, wherein providing the radiation absorbing film comprises using physical vapor deposition to deposit the radiation absorbing film on the surface of the rigid carrier.
